(19) United States
(12) Patent Application Publication
(10) Pub. No.: US 2018/0177073 A1
(43) Pub. Date: Jun. 21, 2018

(54) COMPRESSION FIT HEAT SINK FOR ELECTRONIC COMPONENTS

(71) Applicant: Delphi Technologies, Inc., Troy, MI (US)

(72) Inventor: Ryan J. Pickens, Auburn Hills, MI (US)

(21) Appl. No.: 15/386,040

(22) Filed: Dec. 21, 2016

(51) Int. Cl. H05K 7/20; H05K 1/11; H05K 1/02; H05K 1/09

(52) U.S. Cl. CPC H05K 7/209; H05K 1/09; H05K 1/021; H05K 1/115

(57) ABSTRACT

An electronic assembly includes a printed-circuit-board, an electronic-component, and a heat-sink-element. The printed-circuit-board has a first-surface and a second-surface opposite said first surface. The printed-circuit-board defines a via that connects the first-surface to the second-surface. The electronic-component defines a top-surface and a mounting-surface. The mounting-surface is in direct-contact with the printed-circuit-board. The heat-sink-element is in compressive-contact with both the electronic-component and the printed-circuit-board. The heat-sink-element defines a fin, a shank, and a contact-section therebetween. The contact-section rests on the top-surface, the fin extends above the top-surface, and the shank extends through the via of the printed-circuit-board and beyond the second-surface. The heat-sink-element is configured to transfer heat from the contact-section to the fin and the shank.

### TECHNICAL FIELD OF INVENTION

This disclosure generally relates to an electronic assembly, and more particularly relates to a heat-sink used in and electronic-assembly.

### BACKGROUND OF INVENTION

It is known to attach heat-sinks to electrical-components in an electronic assembly. Heat-sinks typically require a significant amount of space on the electronic assembly and reduce the number and spacing of electronic-components mounted to a printed circuit board. In addition, the mounting requirements of the heat-sink typically add significant mass to the electronic-assembly.

The subject matter discussed in the background section should not be assumed to be prior art merely as a result of its mention in the background section. Similarly, a problem mentioned in the background section or associated with the subject matter of the background section should not be assumed to have been previously recognized in the prior art. The subject matter in the background section merely represents different approaches, which in and of themselves may also be inventions.

### SUMMARY OF THE INVENTION

In accordance with one embodiment, an electronic-assembly is provided. The electronic assembly includes a printed-circuit-board, an electronic-component, and a heat-sink-element. The printed-circuit-board has a first-surface and a second-surface opposite the first surface. The printed-circuit-board defines a via that connects the first-surface to the second-surface. The electronic-component defines a top-surface and a mounting-surface. The mounting-surface is in direct-contact with the printed-circuit-board. The heat-sink-element is in compressive-contact with both the electronic-component and the printed-circuit-board. The heat-sink-element defines a fin, a shank, and a contact-section therebetween. The contact-section rests on the top-surface, the fin extends above the top-surface, and the shank extends through the via of the printed-circuit-board and beyond the second-surface. The heat-sink-element is configured to transfer heat from the contact-section to the fin and the shank.

Further features and advantages will appear more clearly on a reading of the following detailed description of the preferred embodiment, which is given by way of non-limiting example only and with reference to the accompanying drawings.

### BRIEF DESCRIPTION OF DRAWINGS

The present invention will now be described, by way of example with reference to the accompanying drawings, in which:

FIG. 1 is an illustration an electronic-assembly showing of a side-view of a heat-sink-element in accordance with one embodiment;

FIG. 2 is an illustration of the electronic-assembly of FIG. 1 showing a front-view of the heat-sink-element in accordance with one embodiment;

FIG. 3 is an illustration of the electronic-assembly of FIG. 1 showing a back-view of the heat-sink-element in accordance with one embodiment; and

FIG. 4 is an illustration of the electronic-assembly of FIG. 1 showing a top-view of the heat-sink-element in accordance with one embodiment.

### DETAILED DESCRIPTION

FIG. 1 illustrates a non-limiting example of an electronic-assembly 10 that includes a printed-circuit-board 12 (hereafter referred to as the PCB 12), an electronic-component 14, and a heat-sink-element 16. The PCB 12 includes a first major surface, e.g. top surface, hereinafter referred to as the first-surface 18 and a second major surface, e.g. bottom surface, opposite the first-surface 18, hereinafter referred to as the second-surface 20. The PCB 12 may be formed of circuit board substrates that are made of epoxy or polyimide resins. The resin may be reinforced with a woven glass cloth or other matrix such as chopped fibers. Substrates formed of such materials are typically referred to as FR-4 or G-10 type circuit boards. The circuit board substrate may alternatively be constructed of ceramic or rigid polymer materials. This listing of acceptable substrate materials is not exhaustive and other materials may also be used successfully. A layer of conductive material, such as a copper based material is electroplated on at least one major surface of the circuit board substrate. The layer of conductive material is then formed to create the conductive traces and conductive pads (not shown) on either of the first-surface 18 and the second-surface 20, typically by using a chemical etching process. The PCB 12 may also include various electronic-components 14 including, but not limited to, capacitors, resistors, inductors, amplifiers, micro-processors, etc. as will be recognized by one skilled in the art.

The PCB 12 defines a via 22 that connects the first-surface 18 to the second-surface 20 and the via defines a wall 24. The wall 24 of the via 22 may be metallized 26 e.g. by an electroplating process to create a path of conduction between the first-surface 18 and the second-surface 20. The metallization 26 may be any conductive-material suitable for use on the PCB 12 including, but not limited to, alloys of copper, silver, gold, palladium, tin, bismuth, antimony, and germanium.

The electronic-component 14 defines a top-surface 28 and a mounting-surface 30, wherein the mounting-surface 30 and is in direct-contact with the PCB 12. The electronic-component 14 may be attached to the PCB 12 by a conductive solder, such as SAC305 manufactured by AIM Metals & Alloys LP, of Cranston, R.I., USA. The attachment of the electronic-component 14 to the PCB 12 may be performed by a vapor phase reflow process, or any of the known soldering processes that are compatible with the selected solder alloy. Other known methods of attaching the electronic-component 14 to the PCB 12 are contemplated, but not shown, such as wire-bonding, adhesives, mechanical fasteners, and will be understood by those in the art.

As illustrated in FIG. 1, the heat-sink-element 16 may be in compressive-contact with both the electronic-component 14 and the PCB 12 as a result of a spring-force (not shown) developed from the geometry of the heat-sink-element 16. The heat-sink-element 16 defines a fin 32, a shank 34, and a contact-section 36 therebetween. The contact-section 36 rests on the top-surface 28 of the electronic-component 14 and may transmit a compressive force 38 normal to the top-surface 28. The force 38 may be applied at any value required to maintain contact between the contact-section 36 and the top-surface 28, and is preferably greater than 34 Kilopascals (kPa) and less than 586 kPa. A dimension of the contact-section 36 is preferably the same as the dimension of the top-surface 28 to advantageously distribute the force 38 evenly across the electronic-component 14, and to maximize the contact-area between the top-surface 28 and the heat-sink-element 16. The force 38 may help to retain the electronic-component 14 during processes such as handling and soldering. The heat-sink-element 16 may be fabricated from a conductive material including, but not limited to alloys of, copper, aluminum, nickel, silver, gold, platinum, and palladium. The conductive material may be plated with another material, including, but not limited to, tin. The heat-sink-element 16 is preferably fabricated from the copper alloy designated as CDA210 and/or DCA151 with a stock thickness of between 0.5 millimeters (0.5 mm) and 1.0 mm, and preferably a stock thickness of between 0.826 mm and 1.0 mm.

The fin 32 may extend above the top-surface 28 in any direction and for any distance. As illustrated in FIG. 1, the fin 32 extends in a vertical-direction above the top-surface 28 for illustration purposes only. The angle and/or curvature of the fin 32 may be adjusted based on manufacturing constraints, and the length of the fin 32 may be adjusted based on a desired radiation of heat 40 as will be described below.

The shank 34 extends through the via 22 of the PCB 12 and beyond the second-surface 20. The shank 34 may extend beyond the second-surface 20 in any direction and for any distance. As illustrated in FIG. 1, the shank 34 extends in a vertical-direction below the second-surface 20 for illustration purposes only. The angle and/or curvature of the shank 34 may be adjusted based on manufacturing constraints, and the length of the shank 34 may be adjusted based on the desired radiation of heat 40 as will be described below.

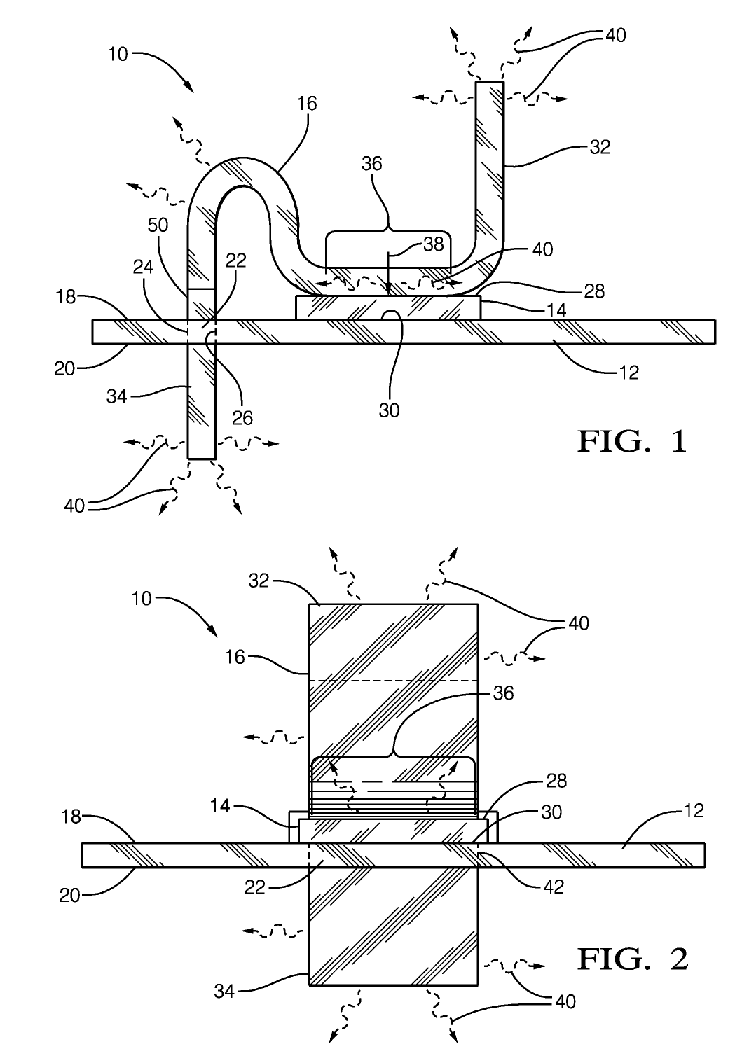

As illustrated in FIG. 2, the shank 34 may have an interference-fit 42 with the via 22 to retain the heat-sink-element 16 within the PCB 12. The interference-fit 42 is defined as a line-to-line contact between the surface of the shank 34 and the wall 24 of the via 22. The shank 34 may displace material at the wall 24 of the via 22 during insertion to create the interference-fit 42. It will be understood by those in the art that a pull-out-force (not shown) required to remove the shank 34 from the via 22 must be greater than the normal force 38 described above in order for the heat-sink-element 16 to remain seated, and that the pull-out-force may be a function of the amount of interference-fit 42. The amount of interference-fit 42 may be controlled by the dimensions of the via 22 and the shank 34, and will be understood by those skilled in the art. The shank 34 may also include a taper (not shown) to aid in the insertion of the shank 34 into the via 22.

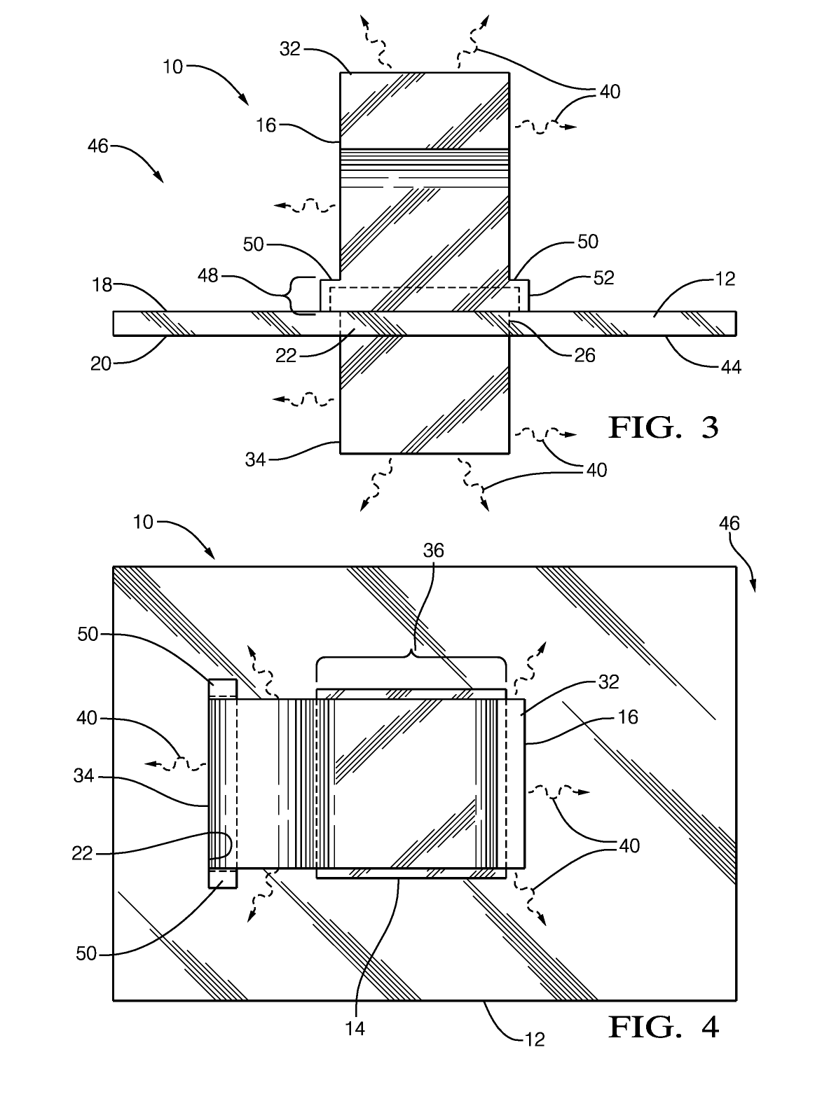

As illustrated in FIGS. 1 and 3, the wall 24 of the via 22 may be metallized 26 with an alloy compatible with the circuits on the PCB 12, and is typically an alloy of copper. The shank 34 may be metallurgically bonded to the wall 24 of the via 22 to further increase the pull-out-force needed to retain the heat-sink-element 16. The bonding of the shank 34 to the wall 24 may be performed using the vapor phase reflow process described above, or any of the known soldering processes that are compatible with the selected solder alloy described above.

As illustrated in FIG. 3, the PCB 12 may contain a conductive-trace 44 configured to function as a grounding-node for the one or more electronic-components 14 attached to the PCB 12. The conductive-trace 44 may be any conductive-material and is preferably an alloy of copper. The conductive-trace 44 may be located within the PCB 12 or attached to an external-surface, and is shown as being attached to the second-surface 20 in FIG. 1 for illustration purposes only. The metallized 26 wall 24 of the via 22 may be in contact with the conductive-trace 44 to advantageously ground the heat-sink-element 16 in addition to creating a path of heat 40 conduction from other areas and other electronic-components 14 of the PCB 12.

The heat-sink-element 16 is configured to transfer heat 40 from the contact-section 36 to the fin 32 and the shank 34, wherein the heat 40 may be radiated into the surrounding-environment 46 (FIGS. 3 and 4). The surrounding-environment 46 may be within a sealed or vented enclosure (not shown) into which the heat 40 may radiated. The surrounding-environment 46 may then transfer the heat 40 to the enclosure. The heat-sink-element 16 advantageously radiates heat 40 on both the first-surface 18 and the second-surface 20 of the PCB 12 thereby increasing the heat-transfer efficiency of the electronic-assembly 10. Experimentation by the inventor has indicated that the heat-sink-element 16 may reduce the required area of prior art heat-sink-pads (not shown) on the PCB 12 by as much as 30% for electronic assemblies in engine-compartment vehicle applications.

The heat-sink-element 16 may also contain an appendage 48 (FIG. 3) defining a shoulder 50 and a stop 52, wherein the shoulder 50 is configured to insert the shank 34 into the via 22 and the stop 52 is configured to seat the shank 34 against the first-surface 18. The shoulder 50 and stop 52 may be located on one or preferably both sides of the shank 34. The amount of overlap created by the appendage 48 onto the first-surface 18 may be user-defined based on the lay-out of the PCB 12 and the insertion-tool (not shown). The surfaces created by the shoulder 50 and the stop 52 may be parallel to the first-surface 18 to maximize the available area for engaging an insertion-tool and for seating the heat-sink-element 16.

Accordingly, an electronic-assembly 10, and a heat-sink-element 16 for the electronic-assembly 10 is provided. The heat-sink-element 16 will impart a force 38 normal to the electronic-component 14 increasing the conduction of heat 40, and radiate heat 40 on both sides of the PCB 12. In addition, the heat-sink-element 16 requires less surface area on the PCB 12 compared to the prior art heat-sinks and utilizes the vertical space available within the enclosure. The heat-sink-element 16 will enhance the thermal cooling capability of the electronic-assembly 10 and allow for an increased component density potentially reducing the overall package size of the electronic-assembly 10.

While this invention has been described in terms of the preferred embodiments thereof, it is not intended to be so limited, but rather only to the extent set forth in the claims that follow. Moreover, the use of the terms first, second, upper, lower, etc. does not denote any order of importance, location, or orientation, but rather the terms first, second, etc. are used to distinguish one element from another. Furthermore, the use of the terms a, an, etc. do not denote a limitation of quantity, but rather denote the presence of at least one of the referenced items.

1. An electronic assembly, comprising:
a printed-circuit-board having a first-surface and a second-surface opposite said first surface, said printed-circuit-board defining a via that connects the first-surface to the second-surface;
an electronic-component, said electronic-component defining a top-surface and a mounting-surface, wherein the mounting-surface is in direct-contact with the printed-circuit-board; and
a heat-sink-element in compressive-contact with both the electronic-component and the printed-circuit-board, said heat-sink-element defining only a single fin, a shank, and a contact-section therebetween, wherein the contact-section rests on the top-surface, the single fin extends above the top-surface, and the shank extends through the via of the printed-circuit-board and beyond the second-surface, and wherein the heat-sink-element is configured to transfer heat from the contact-section to the single fin and the shank.

2. The electronic assembly in accordance with claim 1, wherein the shank has an interference-fit with the via.

3. The electronic assembly in accordance with claim 2, wherein a wall of the via is metallized and the shank is metallurgically bonded to the wall of the via.

4. The electronic assembly in accordance with claim 3, wherein the printed-circuit-board contains a conductive-trace and the wall of the via is in contact with the conductive-trace.

5. The electronic assembly in accordance with claim 1, wherein the heat-sink-element imparts a compressive force normal to the top-surface of the electronic-component.

6. The electronic assembly in accordance with claim 1, wherein the heat-sink-element is comprised of a conductive-material.

7. The electronic assembly in accordance with claim 6, wherein the conductive-material is selected from the list of copper, aluminum, nickel, silver, gold, platinum, palladium, and alloys thereof.

8. The electronic assembly in accordance with claim 1, wherein the heat-sink-element contains an appendage defining a shoulder and a stop, wherein the shoulder is configured to insert the shank into the via and the stop is configured to seat the shank against the first-surface.
